(19) United States
(12) Patent Application Publication
(10) Pub. No.: US 2005/0279995 A1
(43) Pub. Date: Dec. 22, 2005

(54) Composition for preparing organic insulating film and organic insulating film prepared from the same

(75) Inventors: Jung Han Shin, Gyeonggi-Do (KR); Tae Woo Lee, Seoul (KR); Sang Yoon Lee, Seoul (KR); Hyung Jung Park, Seoul (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-do (KR)

(21) Appl. No.: 11/007,352

(22) Filed: Dec. 9, 2004

(30) Foreign Application Priority Data
Jun. 21, 2004 (KR) 10-2004-0046177

(51) Int. Cl. H01L 29/08

(52) U.S. Cl. 257/40

(57) ABSTRACT

A composition for preparing an organic insulating film. The composition includes a functional group-containing monomer, an initiator generating an acid or a radical upon light irradiation or heating, and a linear polymer. Further, an organic insulating film prepared from the composition. Since the organic insulating film has a crosslinked structure, it exhibits solvent resistance in subsequent processes. Further, when the organic insulating film is used to fabricate a transistor, it can improve the electrical properties of the transistor.

### BACKGROUND OF THE INVENTION

This non-provisional application claims priority under 35 U.S.C. 119(a) on Korean Patent Application No. 200446177 filed on Jun. 21, 2004 which is herein expressly incorporated by reference.

A. Field of the Invention

The present invention relates to a composition for preparing an organic insulating film, and an organic insulating film prepared from the composition. More specifically, the present invention relates to a composition for preparing a crosslinked organic insulating film having chemical resistance to organic solvents used in subsequent processes after preparation of the organic insulating film, and an organic insulating film prepared from the composition.

B. Description of the Related Art

Since polyacetylenes as conjugated organic polymers exhibiting semiconductor characteristics were developed, organic semiconductors have been actively investigated as novel electrical and electronic materials in a wide variety of applications, e.g., functional electronic and optical devices. In terms of various manufacturing processes, these organic semiconductors exhibit easy molding into fibers and films, superior flexibility, high conductivity and low manufacturing costs.

Among devices fabricated by using these electrically conductive polymers, research on organic thin film transistors fabricated by using organic materials as semiconductor active layers has been conducted since the 1980's. In this connection, a number of studies are now being actively undertaken around the world. Organic thin film transistors are substantially identical to silicon (Si) thin film transistors in terms of their structure, but have a great difference in that organic materials are used as the semiconductor materials instead of silicon (Si). In addition, such organic thin film transistors have advantages in that they can be fabricated by printing processes at ambient pressure, and further by roll-to-roll processes using plastic substrates, instead of conventional silicon processes such as plasma-enhanced chemical vapor deposition (CVD). This provides an economic advantage for such organic thin film transistors over silicon thin film transistors.

Organic thin film transistors are expected to be useful for driving devices of active displays and plastic chips for use in smart cards and inventory tags, and are comparable to α-Si thin film transistors in terms of performance. The performance of organic thin film transistors is dependent on the degree of crystallization of organic active layers, charge characteristics at the interfaces between substrates and organic active layers, and carrier injection ability into the interfaces between source/drain electrodes and organic active layers. There have been a number of trials to improve the performance of organic thin film transistors. Particularly, in an attempt to decrease a threshold voltage, insulators having a high dielectric constant, for example, ferroelectric insulators, such as BaₓSr₁₋ₓTiO₃ (barium strontium titanate (BST)), Ta₂O₅, Y₂O₃, TiO₂, etc., and inorganic insulators, such as PbZrₓTi₁₋ₓO₃ (PZT), Bi₄Ti₃O₁₂, BaMgF₄, SrBi₂(Ta₁₋ₓNbₓ)₂O₉, Ba(Zr₁₋ₓTi)O₃ (BZT), BaTiO₃, SrTiO₃, Bi₄Ti₃O₁₂, etc., have been used as materials for inorganic insulating films (U.S. Pat. No. 5,946,551). However, these inorganic oxide materials do not have a significant advantage over conventional silicon materials in terms of processing.

As materials for organic insulating films, polyimide, benzocyclobutene (BCB), photoacryls and the like have been used (U.S. Pat. No. 6,232,157). However, since these organic insulating films exhibit unsatisfactory device characteristics over inorganic insulating films, they are unsuitable to replace inorganic insulating films.

On the other hand, Infineon Technology attempted to improve the chemical resistance in a subsequent process by mixing polyvinylphenol (PVP) with polymelamine-co-formaldehyde. However, this attempt is limited in its application to plastic substrates since a temperature as high as 200° C. is required to crosslink the PVP (Journal of Applied Physics 2003, 93, 2977 & Applied Physics Letter 2002, 81, 289).

### SUMMARY OF THE INVENTION

Therefore, the present invention has been made in view of the above problems of the related art, and it is an object of the present invention to provide a composition for preparing an organic insulating film having chemical resistance to organic solvents used during subsequent processing. Accordingly, when an organic insulating film prepared from the composition is used to fabricate a transistor, it can improve the electrical performance of the transistor while enabling formation of micropatterns.

It is another object of the present invention to provide an organic insulating film prepared from the composition.

It is yet another object of the present invention to provide an organic thin film transistor fabricated by using the organic insulating film.

In accordance with one embodiment of the present invention, there is provided a composition for preparing an organic insulating film comprising three elements. The first element is a functional group-containing monomer, the monomer containing at least one epoxide group or radical-polymerizable group. The epoxy group is selected from the group of compounds represented in the following Formula Set 1: 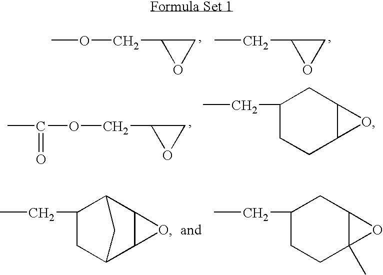
The one radical-polymerizable group is selected from the group of compounds represented in the following Formula Set 2: 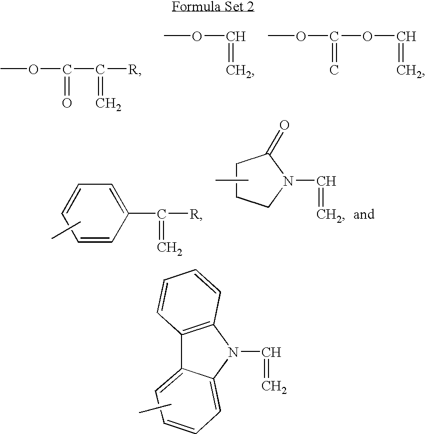
wherein R is hydrogen or methyl.

The second element is an initiator generating an acid or a radical upon light irradiation or heating and the third element is a linear polymer.

In accordance with another embodiment of the present invention, there is provided an organic insulating film prepared by coating a surface with the composition, followed by annealing and exposure to UV irradiation.

In accordance with yet another embodiment of the present invention, there is provided an organic thin film transistor comprising a substrate, a gate electrode, a gate insulating layer, an organic active layer and source-drain electrodes wherein the organic insulating film of the present invention is used as the gate insulating layer.

### BRIEF DESCRIPTION OF THE DRAWINGS

The above and other objects, features and other advantages of the present invention will be more clearly understood from the following detailed description taken in conjunction with the accompanying drawing, in which:

FIG. 1 is a graph showing the current transfer characteristics of an organic thin film transistor fabricated in Example 1 of the present invention.

FIG. 2 is a schematic drawing of an exemplary organic thin film transistor.

### DESCRIPTION OF THE PREFERRED EMBODIMENTS

Hereinafter, embodiments of the present invention will be explained in more detail.

The functional group-containing monomer included in the composition of the present invention is either a compound containing at least one epoxide group selected from the group of compounds represented in the following Formula Set 1: 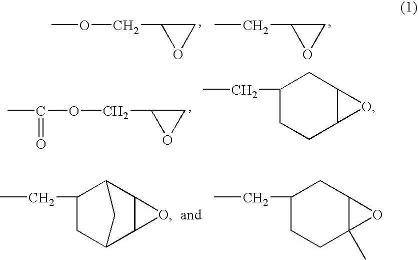
or a compound containing at least one radical-polymerizable group selected from the group of compounds represented in the following Formula Set 2: 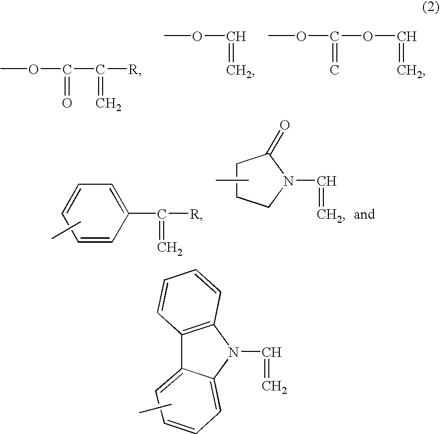
wherein R is hydrogen or methyl.

Examples of suitable compounds containing at least one epoxide group represented by Formula 1 include ethylene glycol diglycidyl ether, 1,4-butanediol diglycidyl ether, 1,4-cyclohexanedimethanol diglycidyl ether, bisphenol A diglycidyl ether, glycerol diglycidyl ether, glycerol propoxylate triglycidyl ether, triphenylolmethane triglycidyl ether, 4-vinylcylcohexane dioxide, dicyclopentadiene diepoxide, diglycidyl ether, 1,3-bis(3-glycidoxypropyl) tetramethyldisiloxane, 1,2-cyclohexanedicarboxylic acid diglycidyl ester, 1,4-bis(glycidyloxy)benzene, trimethylolpropane triglycidyl ether, 3,7,14-tris[[3-(epoxypropoxy)propyl]dimethylsilyloxy]-1,3,5,7,9,11,14-heptacyclopentyltricyclo[7,3,3,15,11]heptasiloxane, N,N-diglycidylaniline, 9,9-bis[4-(glycidyloxy)phenyl]fluorene, triglycidyl isocyanurate, bis[4-(2,3-epoxy-propylthio)phenyl]sulfide, resorcinol diglycidyl ether, 2,6-di(oxiran-2-ylmethyl)-1,2,3,5,6,7-hexahydropyrrolo[3,4,F] isoindole-1,3,5,7-tetraone, santolink X1-100, 1,2,7,8-diepoxyoctane, 1-methyl-4-(1-methylepoxyethyl)-7-oxabicyclo[4,1,0]heptane, 3,4-epoxycyclohexylmethyl-3,4-epoxycyclohexylcarboxylate, glycidyl acrylate, glycidyl methacrylate, 4,4′-methylenebis(N,N-diglycidylaniline), bis(3,4-epoxycyclohexylmethyl)adipate, 1,2-epoxy-4-vinylcyclohexane, and 2-(3,4-epoxycyclohexyl)ethyltrimethoxysilane.

Examples of the compound containing at least one radical-polymerizable group represented by Formula 2 include methyl methacrylate, allyl acrylate, allyl methacrylate, acrylic acid, methacrylic acid, 2-hydroxyethyl acrylate, 2-hydroxyethyl methacrylate, glycidyl acrylate, bisphenol A dimethacrylate, 2-(dimethylamino)ethyl acrylate, 2-(dimethylamino)ethyl methacrylate, ethylene glycol diacrylate, ethylene glycol dimethacrylate, trimethylolpropane triacrylate, trimethylolpropane trimethacrylate, n-butyl acrylate, n-butyl methacrylate, stearyl acrylate, stearyl methacrylate, 1,6-hexanediol diacrylate, 1,6-hexanediol dimethacrylate, pentaerytritol triacrylate, 2,2,2-trifluoroethyl acrylate, 2,2,2-trifluoroethyl methacrylate, 2-cyanoethyl acrylate, diethylene glycol diacrylate, diethylene glycol dimethacrylate, 2-bromoethyl acrylate, D,L-menthyl acrylate, D,L-menthyl methacrylate, 1H,1H-perfluorooctyl acrylate, 1H,1H-perfluorooctyl methacrylate, 1,1,1,3,3,3-hexafluoroisopropyl acrylate, 1,1,1,3,3,3-hexafluoroisopropyl methacrylate, 1,4-cyclohexanedimethyl 1,4-diacrylate, 1,4-cyclohexanedimethyl 1,4-dimethacrylate, barium methacrylate, zinc methacrylate, methallyl methacrylate, cinnamyl acrylate, cinnamyl methacrylate, acryloxy tri-N-butyltin, methacryloxypropylmethyl dichlorosilane, trimethylsilyl acrylate, trimethylsilyl methacrylate, 2-(methacryloxyl)ethyl acetoacetate, 1,3-bis(3-methacryloxypropyl)tetramethyldisiloxane, 3-methacrylpropyltris(vinyldimethylsiloxy)silane, vinyl acrylate, vinyl acetate, vinyl chloroformate, vinyl trifluoroacetate, 2-chloroethyl vinyl ether, 1,6-hexanediol divinyl ether, di(ethylene glycol) vinyl ether, 2-ethylhexanoic acid vinyl ester, styrene, α-methyl styrene, 4-bromostyrene, 4-acetoxystyrene, 4-methoxystyrene, 2-vinylnaphthalene, 2,3,4,5,6-pentafluorostyrene, 3,4-dimethoxy-1-vinylbenzene, 4-vinylbiphenyl, N-vinyl-2-pyrrolidone, or N-vinylcarbazol.

The present invention is characterized in that the functional group-containing monomer is mixed with an initiator, which generates an acid or a radical upon exposure to UV irradiation or heating. This is followed by annealing and exposure to UV irradiation, which induces ring-opening or initiates polymerization of the monomer, and thereby forms a crosslinked structure.

Examples of acid-generating initiators usable in the present invention include: ionic photoacid generators, including sulfonium- and iodonium-based materials, e.g., triphenylsulfonium trifluoromethanesulfonate, triphenylsulfonium perfluorooctanesulfonate, diphenyl-p-tolylsulfonium perfluorooctanesulfonate, tris(p-tolyl)sulfonium perfluorooctanesulfonate, tris(p-chlorobenzene)sulfonium trifluoromethanesulfonate, tris(p-tolyl)sulfonium trifluoromethanesulfonate, trimethylsulfonium trifluoromethanesulfonate, dimethylphenylsulfonium trifluoromethanesulfonate, dimethyltolylsulfonium trifluoromethanesulfonate, dimethyltolylsulfonium perfluorooctanesulfonate, triphenylsulfonium p-toluenesulfonate, triphenylsulfonium methanesulfonate, triphenylsulfonium butanesulfonate, triphenylsulfonium n-octanesulfonate, triphenylsulfonium 1-naphthalenesulfonate, triphenylsulfonium 2-naphthalenesulfonate, triphenylsulfonium 10-camphorsulfonate, triphenylsulfonium 2,5-dichlorobenzenesulfonate, diphenyltolylsulfonium 1,3,4-trichlorobenzenesulfonate, dimethyltolylsulfonium p-toluenesulfonate, diphenyltolylsulfonium 2,5-dichlorobenzenesulfonate, triphenylsulfonium chloride, triphenylsulfonium bromide, triphenylsulfonium tetrafluoroborate, triphenylsulfonium pentafluoroantimonate, triphenylsulfonium pentafluorophosphate, triphenylsulfonium pentafluoroarsenate, diphenyliodonium trifluoromethanesulfonate, bis(4-t-butylphenyl)iodonium 1,1,1,3,3,3-hexafluoro-2-trifluoromethylpropane-2-sulfonate, bis(4-t-butylphenyl)iodonium (7,7-methyl-6-oxo-bicyclo[2.2.1]heptyl)-methanesulfonate, and bis(4-t-butylphenyl)iodonium p-toluenesulfonate; non-ionic photoacid generators, including nitrobenzylsulfonate derivatives, imidosulfonate derivatives and azonaphthoquinone derivatives, e.g., 2-nitrobenzyl p-toluenesulfonate, 2,6-dinitrobenzyl p-toluenesulfonate, p-nitrobenzyl 9,10-dimethoxyanthracene-2-sulfonate, norbornene imidosulfonate, cyclohexyl tosylate, diazobismethanesulfonylbenzene, and bis(cyclohexyl)diazomethane; and polymeric photoacid generators having a weight-average molecular weight of 500˜100,000, and containing a sulfonium or iodonium salt in their backbone or side chain or an organic photoacid generating group in their side chain.

Examples of radical-generating initiators usable in the present invention include common organic peroxide and azo compounds. Specific examples include: benzoyl peroxide, lauroyl peroxide, t-butyl hydroperoxide, acetylcyclohexanesulfonyl peroxide, isobutyroyl peroxide, di(2-ethylhexyl) peroxydicarboxylate, diisopropyl peroxydicarboxylate, t-butyl peroxypivalate, decanoyl peroxide, and azobis(2-methylpropionitrile).

Other examples of radical-generating initiators usable in the present invention include alpha-hydroxyketones, alpha-aminoketones, benzyldimethyl ketals, benzoin, benzoin methyl ether, benzoin ethyl ether, benzoin n-propyl ether, benzoin isopropyl ether, benzoin n-butyl ether, benzophenone, paramethyl benzophenone, acetophenone, anthraquinone, phenyl disulfide, and 2-nitrofluorene. In this case, photosensitizers, such as tertiary amines, alkylphosphines and thioethers, can be additionally used.

The content of the initiator in the composition according to an embodiment of the present invention is in the range of 0.1˜10 parts by weight, based on 100 parts by weight of the functional group-containing monomer, but is not limited to this range. When the initiator is used in an amount exceeding 10 parts by weight, there is a problem that the crosslinked mixture may be gelled. On the other hand, when the initiator is used in an amount below 0.1 parts by weight, the degree of crosslinking may be low, deteriorating the solvent resistance of a thin film to be prepared.

The linear polymer included in the composition of the present invention is one having a molecular weight between 1,000 and 1,000,000 and is selected from the group consisting of polyvinylphenols and their derivatives, polyvinylalcohols and their derivatives, polyacryls and their derivatives, polynorbornenes and their derivatives, cellulose derivatives, and copolymers thereof. Polymers containing a polar group, such as a hydroxyl or carboxyl group, in their backbone or side chain, are preferred.

Further, the linear polymer may be protected with an acid-labile protecting group. A protected linear polymer is then deprotected by the initiator in order for the linear polymer to be transformed into a linear polymer containing hydroxyl or carboxyl groups. Examples of the acid-labile protecting group include t-butyl, isobornyl, menthyl, 2-methyl-2-adamantanyl, 2-ethyl-2-adamantanyl, tetracyclodecanyl, tetrahydropyranoyl, 3-oxocyclohexanoyl, mevalonic lactonyl, dicyclopropylmethyl, methylcyclopropylmethyl, methylethylether groups, and others.

The content of the linear polymer in the composition of an embodiment of the present invention is preferably in the range of from 1 part to 10,000 parts by weight, based on 100 parts by weight of the functional group-containing monomer. If the linear polymer is used in an amount of more than 10,000 parts by weight, there are dangers of low degree of crosslinking and poor electrical properties. Meanwhile, if the linear polymer is used in an amount of less than 1 part by weight, formation of a thin film is difficult and thus effective electrical properties are difficult to attain.

The organic insulating film of the present invention may be prepared by coating the composition on a substrate, on which a gate electrode is formed. Alternatively, the organic insulating film may be prepared by coating the composition on an organic active layer on which source-drain electrodes are formed. The coating may be carried out by spin coating, spin casting, dip coating, spray coating, roll coating, ink-jet printing, etc.

Additionally, a solvent capable of dissolving the composition of the present invention may be used in such a way that a thin film to be prepared after coating has a sufficient thickness. The solvent can be used in an amount of 1%˜80% by weight, based on the total weight of the composition. Examples of suitable organic solvents include: cyclohexanone, chloroform, chlorobenzene, ethyleneglycolmonomethylether, propyleneglycolmethylether acetate, ethyl lactate, toluene, xylene, methyl ethyl ketone, 4-heptanone, methanol, butanol, acetone, N-methylformamide, N-methylpyrrolidone, and triphenylimidazole.

The thin film prepared after coating is annealed at 50˜150° C. for 1˜60 minutes, and exposed to UV irradiation to prepare the final organic insulating film. The order of the annealing and exposure to UV irradiation may be inverted. In addition, the two processes may be repeatedly carried out one or more times.

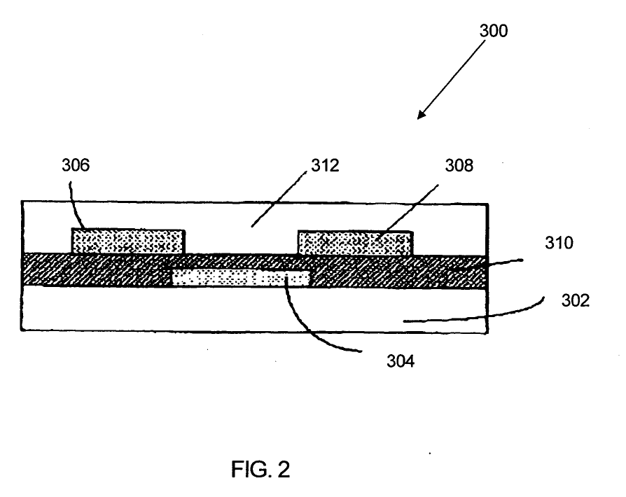

As exemplified in FIG. 2, the organic insulating film thus prepared can be used to fabricate an organic thin film transistor 300 comprising a substrate 302, a gate electrode 304, a gate insulating layer 310, an organic active layer 312, and source-drain electrodes 306 and 308. At this time, the organic insulating film of the present invention is used as the gate insulating layer 310.

Specific examples of materials for the organic active layer include, but are not limited to, pentacenes, copper phthalocyanines, polythiophenes, polyanilines, polyacetylenes, polypyrroles, polyphenylene vinylenes and derivatives thereof.

Suitable materials for the gate electrode and the source-drain electrodes are metals and electrically conductive polymers commonly used in the art. Specific examples include, but are not limited to, gold, silver, aluminum, nickel, indium-tin oxides, polythiophenes, polyanilines, polyacetylenes, polypyrroles, polyphenylene vinylenes, and polyethylenedioxythiophene (PEDOT)/polystyrenesulfonate (PSS).

Materials usable as the substrate include, but are not limited to, glass, silicon wafer, polyethyleneterephthalate (PET), polycarbonate (PC), polyethersulfone (PES) and polyethylenenaphthalate (PEN), and the like.

The present invention will now be explained in more detail with reference to the following examples. However, these examples are given for the purpose of illustration and are not to be construed as limiting the scope of the invention.

### PREPARATIVE EXAMPLE 1

### Preparation of a Composition for Preparing an Organic Insulating Film by Using a Monomer Containing an Epoxide Group as a Functional Group

2.0 g of trimethylolpropane triglycidyl ether (Aldrich), 0.02 g of triphenylsulfonium triflate (Aldrich), 0.02 g of benzoyl peroxide (Aldrich), and 2.0 g of polyvinylphenol (Aldrich) having a weight-average molecular weight of 8,000 were dissolved in 18 mL of cyclohexanone to give a composition for preparing an organic insulating film.

### PREPARATIVE EXAMPLE 2

### Preparation of a Composition for Preparing an Organic Insulating Film by Using a Monomer Containing a Radical-Polymerizable Group as a Functional Group

1.0 g of trimethylolpropane trimethacrylate (Aldrich), 0.01 g of triphenylsulfonium triflate (Aldrich), 0.01 g of benzoyl peroxide (Aldrich), and 3.0 g of polyvinylphenol (Aldrich) having a weight-average molecular weight of 8,000 were dissolved in 27 mL of cyclohexanone to give a composition for preparing an organic insulating film.

### COMPARATIVE PREPARATION EXAMPLE 1

### Preparation of a Composition for the Preparation of an Organic Insulating Film without Using any Functional Group-Containing Monomer or Initiator

3.0 g of polyvinylphenol (Aldrich) having a weight-average molecular weight of 8,000 was dissolved in 27 mL of cyclohexanone to give a composition for preparing an organic insulating film.

### EXAMPLE 1

### Fabrication of an Organic Thin Film Transistor by Using a Monomer Containing an Epoxide Group as a Functional Group

In this example, a bottom-contact organic thin film transistor was fabricated. First, Al was deposited on a washed glass substrate by a vacuum deposition technique to form a gate electrode having a thickness 1,500 Å. The composition prepared in Preparative Example 1 was then spin-coated on the gate electrode to a thickness of 5,000 Å at 4,000 rpm, prebaked at 100° C. for 5 minutes, irradiated by UV light at 600 W for 10 minutes, and baked at 100° C. for 1 hour to prepare the resulting organic insulating film. Next, Au was deposited on the organic insulating film to a thickness of 1,000 Å, and was subjected to a photolithographic process to form an Au electrode pattern. Pentacene was deposited on the Au electrode pattern to a thickness of 1,000 Å by organic molecular beam deposition (OMBD) under a vacuum of 2×10⁻⁷ torr at a substrate temperature of 50° C. and a deposition rate of 0.85 Å/sec. to fabricate an organic thin film transistor.

### EXAMPLE 2

### Fabrication of an Organic Thin Film Transistor by Using a Monomer Containing a Radical-Polymerizable Group as a Functional Group

An organic thin film transistor was fabricated in the same manner as in Example 1, except that the composition prepared in Preparative Example 2 was used instead of the composition prepared in Preparative Example 1.

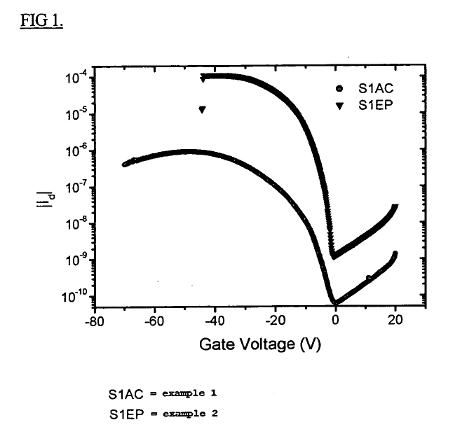

The current transfer characteristics of the devices fabricated in Examples 1 and 2 were measured using a KEITIHLEY semiconductor characterization system (4200-SCS), and curves were plotted (FIG. 1). The electrical properties of the devices calculated from the curves are shown in Table 1.

### COMPARATIVE EXAMPLE 1

### Fabrication of an Organic Thin Film Transistor without Using any Functional Group-Containing Monomer or Initiator

An organic thin film transistor was fabricated in the same manner as in Example 1, except that the composition prepared in Comparative Preparation Example 1 was coated, and baked at 100° C. for 1 hour without involving subsequent exposure to UV irradiation and annealing. As a result, since the obtained organic insulating film was dissolved in the solvent used in the photolithographic process, a curve showing the current transfer characteristics of the organic thin film transistor could not be plotted.

TABLE 1

| | Charge mobility | Off-state leakage | On/off current |
|---|---|---|---|
| | (cm²/Vₛ) | current, I_{off}(A) | ratio, Iₒₙ/I_{off} |
| Example 1 | 0.9 | 10⁻¹⁰ | 10⁵ |
| Example 2 | 1.3 | 10⁻¹¹ | 10⁵ |

The charge mobility was calculated from the slope of the (I_{SD})^{1/2}−V_{G} graph using the following current equation at the saturation region:

$$\begin{matrix}{I}_{SD} = \frac{{WC}_{0}}{2 L} {μ ( {V}_{G} - {V}_{T} )}^{2} \\ \sqrt{{I}_{SD}} = \sqrt{\frac{μ {C}_{0} W}{2 L}} ( {V}_{G} - {V}_{T} ) \\ slope = \sqrt{\frac{μ {C}_{0} W}{2 L}} \\ {μ}_{FET} = {( slope )}^{2} \frac{2 L}{{C}_{0} W}\end{matrix}$$

where I_{SD} is the source-drain current, μ and μ_{FET} are the charge mobility, Cₒ is the capacitance of the oxide film, W is the channel width, L is the channel length, V_{G} is the gate voltage, and V_{T} is the threshold voltage.

The off-state leakage current (I_{off}) is a current flowing in the off-state, and was determined from the minimum current in the off-state in the current ratio.

The Iₒₙ/I_{off} current ratio was obtained from the ratio of the maximum current value in the on-state to the minimum current value in the off-state.

As can be seen from Table 1, the organic thin film transistors fabricated in Examples 1 and 2 using the organic insulating films of the present invention showed high on/off current ratio and charge mobility while maintaining low off-state leakage current.

As apparent from the above description, since the organic insulating film of the present invention has chemical resistance to organic solvents used during subsequent processing, it can improve electrical performance of transistors while enabling formation of micropatterns.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A composition for preparing an organic insulating film comprising:
(i) a functional group-containing monomer, the monomer containing at least one epoxide group or radical-polymerizable group,
wherein the epoxide group is selected from the group consisting of those compounds represented in the following Formula Set 1: 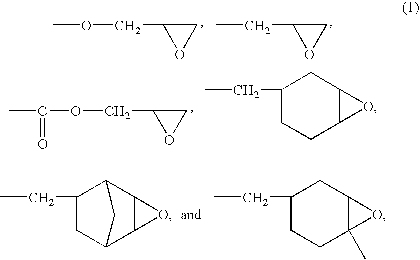
wherein the radical-polymerizable group is selected from the group consisting of those compounds represented in the following Formula Set 2: 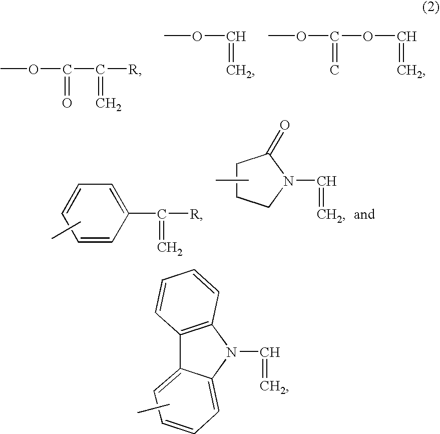
wherein R is hydrogen or methyl;
(ii) an initiator generating an acid or a radical upon light irradiation or heating; and
(iii) a linear polymer.

2. The composition according to claim 1, wherein the acid-generating initiator is selected from the group consisting of ionic photoacid generators, non-ionic photoacid generators and polymeric photoacid generators.

3. The composition according to claim 2, wherein the ionic photoacid generator is selected from the group consisting of sulfonium- and iodonium-based materials.

4. The composition according to claim 2, wherein the non-ionic photoacid generator is selected from the group consisting of nitrobenzylsulfonate, imidosulfonate and azonaphthoquinone derivatives.

5. The composition according to claim 2, wherein the polymeric photoacid generator has a weight-average molecular weight of 500˜100,000 and contains a sulfonium or iodonium salt in its backbone or side chain or an organic photoacid generating group in its side chain.

6. The composition according to claim 1, wherein the radical-generating initiator is selected from the group consisting of organic peroxide and azo compounds.

7. The composition according to claim 1, wherein the radical-generating initiator is selected from the group consisting of benzoyl peroxide, lauroyl peroxide, t-butyl hydroperoxide, acetylcyclohexanesulfonyl peroxide, isobutyroyl peroxide, di(2-ethylhexyl) peroxydicarboxylate, diisopropyl peroxydicarboxylate, t-butyl peroxypivalate, decanoyl peroxide, azobis(2-methylpropionitrile), alpha-hydroxyketones, alpha-aminoketones, benzyldimethyl ketals, benzoin, benzoin methyl ether, benzoin ethyl ether, benzoin n-propyl ether, benzoin isopropyl ether, benzoin n-butyl ether, benzophenone, paramethyl benzophenone, acetophenone, anthraquinone, phenyl disulfide, and 2-nitrofluorene.

8. The composition according to claim 1, wherein the linear polymer is one having a molecular weight between 1,000 and 1,000,000 and is selected from the group consisting of polyvinylphenols and their derivatives, polyvinylalcohols and their derivatives, polyacryls and their derivatives, polynorbornenes and their derivatives, cellulose derivatives, and copolymers thereof.

9. The composition according to claim 8, wherein the linear polymer contains hydroxyl or carboxyl groups in its backbone or side chain.

10. The composition according to claim 8, wherein the linear polymer is protected with an acid-labile protecting group selected from the group consisting of t-butyl, isobornyl, menthyl, 2-methyl-2-adamantanyl, 2-ethyl-2-adamantanyl, tetracyclodecanyl, tetrahydropyranoyl, 3-oxocyclohexanoyl, mevalonic lactonyl, dicyclopropylmethyl, methylcyclopropylmethyl and methylethylether groups.

11. The composition according to claim 1, wherein the initiator is present in an amount of 0.1˜10 parts by weight and the linear polymer is present in an amount of 1˜10,000 parts by weight, based on 100 parts by weight of the functional group-containing monomer.

12. The composition according to claim 1, further comprising 1%˜80% by weight of a solvent selected from the group consisting of cyclohexanone, chloroform, chlorobenzene, ethyleneglycolmonomethylether, propyleneglycolmethylether acetate, ethyl lactate, toluene, xylene, methyl ethyl ketone, 4-heptanone, methanol, butanol, acetone, N-methylformamide, N-methylpyrrolidone and triphenylimidazole, based on the total weight of the composition.

13. An organic insulating film prepared by coating a surface with the composition according to claim 1, followed by annealing at 50˜150° C. for 1˜60 minutes and exposure to UV irradiation.

14. An organic insulating film prepared by coating a surface with the composition according to claim 12, followed by annealing at 50˜150° C. for 1˜60 minutes and exposure to UV irradiation.

15. The organic insulating film according to claim 13, wherein the coating is carried out by a coating technique selected from the group consisting of spin coating, spin casting, dip coating, spray coating, roll coating, and ink-jet printing.

16. An organic thin film transistor comprising a substrate, a gate electrode, a gate insulating layer, an organic active layer and source-drain electrodes wherein the organic insulating film according to claim 13 is used as the gate insulating layer.

17. The organic thin film transistor according to claim 16, wherein the organic active layer is made of a material selected from the group consisting of pentacenes, copper phthalocyanines, polythiophenes, polyanilines, polyacetylenes, polypyrroles, polyphenylene vinylenes and derivatives thereof.

18. The organic thin film transistor according to claim 16, wherein the gate electrode and the source-drain electrodes are made of a material selected from the group consisting of gold, silver, aluminum, nickel, indium-tin oxides, polythiophenes, polyanilines, polyacetylenes, polypyrroles, polyphenylene vinylenes, and polyethylenedioxythiophene (PEDOT)/polystyrenesulfonate (PSS).

19. The organic thin film transistor according to claim 16, wherein the substrate is made of a material selected from the group consisting of glass, silicon wafer, polyethyleneterephthalate (PET), polycarbonate (PC), polyethersulfone (PES), and polyethylenenaphthalate (PEN).
